(19) United States
(12) Patent Application Publication
(10) Pub. No.: US 2026/0016759 A1
(43) Pub. Date: Jan. 15, 2026

(54) SEMICONDUCTOR PROCESS APPARATUS

(71) Applicant: Samsung Electronics Co., Ltd., Suwon-si (KR)

(72) Inventors: Sungmo Yang, Suwon-si (KR); Sungmoon Park, Suwon-si (KR); Heegeun Kim, Suwon-si (KR); Junho Yoon, Suwon-si (KR); Seunghwan Lee, Suwon-si (KR)

(21) Appl. No.: 19/020,416

(22) Filed: Jan. 14, 2025

(30) Foreign Application Priority Data
Jul. 11, 2024 (KR) 10-2024-0092030

(51) Int. Cl. G03F 7/00

(52) U.S. Cl. CPC G03F 7/70608; G03F 7/7075; G03F 7/7085

(57) ABSTRACT

A semiconductor process apparatus includes a stage on which a substrate including a photoresist layer is configured to be seated; a light source configured to irradiate a pulse of light toward the substrate; a sensor configured to generate an output signal in response to reflected light reflected from the substrate; and a controller configured to control the light source and the sensor and to measure the photoresist layer using the output signal, wherein the controller is configured to obtain, from the output signal, a first output signal corresponding to a first beam of the reflected light reflected from a surface of the photoresist layer and a second output signal corresponding to a second beam of the reflected light reflected from a region below a surface of the photoresist layer, and configured to measure the photoresist layer using the first output signal and the second output signal.

### CROSS-REFERENCE TO RELATED APPLICATION

This application claims benefit of priority to Korean Patent Application No. 10-2024-0092030 filed on Jul. 11, 2024 in the Korean Intellectual Property Office, the disclosure of which is incorporated herein by reference in its entirety.

### BACKGROUND

Example embodiments of the present disclosure relate to a semiconductor process apparatus.

A semiconductor process may include a photo process, an etching process, a deposition process, or the like, to form a plurality of layers on a substrate, and a plurality of patterns may be formed in each of the plurality of layers. As a line width of the plurality of patterns and a spacing therebetween decrease, a photolithography process using light of a relatively short wavelength band, such as extreme ultraviolet (EUV) light, has been suggested. A semiconductor process apparatus which may perform a photolithography process using extreme ultraviolet light may preferentially perform measuring of a thickness of a photoresist layer applied to a substrate, a surface profile, or the like, before performing the photolithography process, and yield of the photolithography process may be affected depending on accuracy of the measurement.

### SUMMARY

An example embodiment of the present disclosure is to provide a semiconductor process apparatus which may improve a yield of a photolithography process by accurately measuring a thickness of a photoresist layer applied to a substrate, a surface profile, and the like, before performing a photolithography process using extreme ultraviolet light.

According to an example embodiment of the present disclosure, a semiconductor process apparatus includes a stage on which a substrate including a photoresist layer is configured to be seated; a light source configured to irradiate a pulse of light toward the substrate; a sensor configured to generate an output signal in response to reflected light reflected from the substrate; and a controller configured to control the light source and the sensor and to measure the photoresist layer using the output signal, wherein the controller is configured to obtain, from the output signal, a first output signal corresponding to a first beam of the reflected light reflected from a surface of the photoresist layer and a second output signal corresponding to a second beam of the reflected light reflected from a region below a surface of the photoresist layer, and to measure the photoresist layer using the first output signal and the second output signal.

According to an example embodiment of the present disclosure, a semiconductor process apparatus includes a stage on which a substrate including a photoresist layer is configured to be seated; a light source configured to irradiate a pulse of light having a predetermined duration in each of a plurality of target regions defined along a direction parallel to a surface of the substrate; a sensor configured to receive reflected light reflected from each of the plurality of target regions; and a controller configured to obtain, from an output signal generated by the sensor in response to the reflected light, a first output signal corresponding to a first beam of the reflected light reflected from a surface of the photoresist layer in each of the plurality of target regions, wherein the controller is configured to measure a surface profile of the photoresist layer based on the first output signal.

According to an example embodiment of the present disclosure, a semiconductor process apparatus includes a stage on which a substrate is configured to be seated; a light source configured to irradiate a pulse of light to a surface of the substrate; a sensor configured to generate an output signal in response to reflected light reflected from the substrate; and a controller configured to distinguish between a first output signal and a second output signal, the first output signal corresponding to a first beam of the reflected light directly reflected from the surface of the substrate, and the second output signal corresponding to a second beam of the reflected light traveling to a region below the surface of the substrate and reflected, wherein the controller is further configured to measure a surface profile of the substrate using the first output signal.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a semiconductor process apparatus according to an example embodiment of the present disclosure;

FIG. 2 is a diagram illustrating semiconductor process apparatus according to an example embodiment of the present disclosure;

FIGS. 3 to 5 are diagrams illustrating operations of a semiconductor process apparatus according to an example embodiment of the present disclosure;

FIG. 6 is a diagram illustrating an operation of a semiconductor process apparatus according to an example embodiment of the present disclosure;

FIGS. 7 and 8 are diagrams illustrating operations of a semiconductor process apparatus according to an example embodiment of the present disclosure;

FIGS. 9A to 9C are diagrams illustrating operations of a semiconductor process apparatus according to an example embodiment of the present disclosure;

FIGS. 10A, 10B, 11A, and 11B are diagrams illustrating operations of a semiconductor process apparatus according to an example embodiment of the present disclosure;

FIGS. 12, 13A, 13B, 14, and 15 are diagrams illustrating operations of a semiconductor process apparatus according to an example embodiment of the present disclosure;

FIG. 16 is a flowchart illustrating an operation of a semiconductor process apparatus according to an example embodiment of the present disclosure; and

FIGS. 17A to 17C are diagrams illustrating operations of a semiconductor process apparatus according to an example embodiment of the present disclosure.

### DETAILED DESCRIPTION

Hereinafter, embodiments of the present disclosure will be described as follows with reference to the accompanying drawings.

An item, layer, or portion of an item or layer described as “extending” or as extending “lengthwise” in a particular direction has a length in the particular direction and a width perpendicular to that direction, where the length is greater than the width.

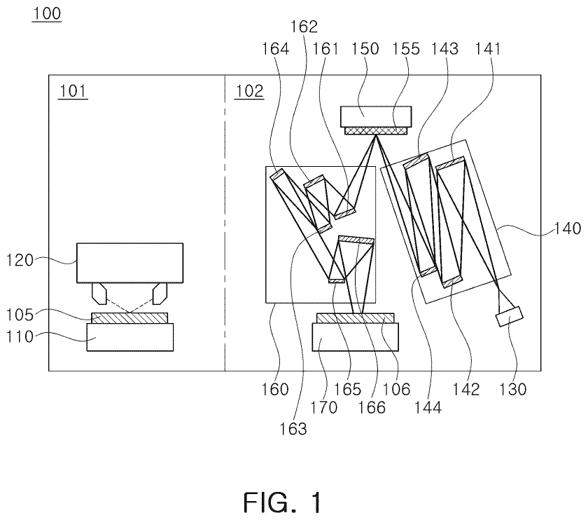

FIG. 1 is a diagram illustrating a semiconductor process apparatus according to an example embodiment.

Referring to FIG. 1, a semiconductor process apparatus 100 according to an example embodiment may be configured as an apparatus for performing a photolithography process and may include a first working space 101 and a second working space 102. The first working space 101 and the second working space 102 may be provided by divided spaces in a housing. The first working space 101 and the second working space 102 may be physically separated from each other by a wall or other separating feature, or may be adjacent regions of a continuous working space. In an example embodiment, the first working space 101 and the second working space 102 may be provided by a single space in a housing.

A substrate 105 coated with a photoresist layer may be disposed in the first working space 101, and a process of measuring the photoresist layer included in the substrate 105 may be performed in the first working space 101. For example, a stage 110 on which the substrate 105 is seated, and a measurement apparatus 120 configured to irradiate the substrate 105 with light, to detect reflected light reflected from the substrate 105 and to perform a measurement of the photoresist layer may be installed in the first working space 101. The measure apparatus 120 may include a light source configured to irradiate the substrate 105 with light, and a sensor configured to detect reflected light reflected from the substrate 105.

In the first working space 101, a surface profile of the photoresist layer included in the substrate 105, and a thickness of the photoresist layer may be measured. When it is determined that the process of coating the photoresist layer is properly performed as a result of performing the measurement process in the first working space 101, the substrate 105 may move to the second working space 102 in which the photolithography process is performed.

In the second working space 102, an extreme ultraviolet lighting unit 130, an illumination optical system 140, a mask stage 150, a projection optical system 160, and a substrate stage 170 may be installed. In an example embodiment, the extreme ultraviolet lighting unit 130, the illumination optical system 140, the mask stage 150, the projection optical system 160, and the substrate stage 170 may be integrated and controlled by a single controller together with the stage 110 and the measurement apparatus 120 installed in the first working space 101. However, in example embodiments, the controller configured to the measurement process in the first working space 101 and the controller configured to the photolithography process in the second working space 102 may be provided separately.

Although not illustrated, the one or more controllers that may be provided separately or together may include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the processing controller 1020 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the one or more controllers may include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The extreme ultraviolet lighting unit 130 may generate and emit extreme ultraviolet light having a high energy density in a wavelength range of several nanometers to several tens of nanometers. In an example embodiment, the extreme ultraviolet lighting unit 130 may generate and output extreme ultraviolet light having high energy density in a wavelength range of 13.5 nm. The extreme ultraviolet lighting unit 130 may include a plasma-based light source and/or a synchrotron radiation light source.

In an example embodiment, the extreme ultraviolet lighting unit 130 may output extreme ultraviolet light using plasma. The light source may operate in a laser-produced plasma (LPP) mode in which a high-power laser is irradiated to a droplet formed of one of materials such as tin, lithium, and xenon to generate plasma, or in a discharge-produced plasma (DPP) mode, or in a master oscillator power amplifier (MOPA) mode.

The high-power laser forms plasma by colliding with a droplet supplied by a droplet supply unit, and accordingly, an illumination mirror and a collector for refocusing the extreme ultraviolet light generated by the plasma may be included in the extreme ultraviolet lighting unit 130. The collector may function as a reflector and may be disposed close to the droplet to increase refocusing efficiency. The energy density of the extreme ultraviolet light output by the extreme ultraviolet lighting unit 130 may be increased by an illumination mirror and a collector.

The illumination optical system 140 may include a plurality of illumination mirrors 141-144. In an example embodiment, the illumination optical system 140 may include two or more illumination mirrors 141-144. By the illumination optical system 140, extreme ultraviolet light emitted from the extreme ultraviolet lighting unit 130 may be transmitted to the mask stage 150. The extreme ultraviolet light emitted from the extreme ultraviolet lighting unit 130 may be reflected from the illumination mirrors 141-144 included in the illumination optical system 140 and may be incident to the mask 155 mounted on the mask stage 150.

In an example embodiment, the mask 155 may be configured as a reflective mask including a non-reflective region and/or an intermediate reflective region along with a reflective region. The mask 155 may include a reflective multilayer film for reflecting extreme ultraviolet light on a substrate formed of a low thermal expansion coefficient material (LTEM) such as quartz, and an absorption layer pattern formed on the reflective multilayer film. The reflective multilayer film may have a structure in which layers formed of different materials are stacked. The absorption layer may be formed of TaN, TaNO, TaBO, Ni, Au, Ag, C, Te, Pt, Pd, Cr. However, the material of the absorption layer is not limited to the aforementioned materials, and the absorption layer portion may correspond to the non-reflective region and/or the intermediate reflective region described above.

The mask 155 may reflect extreme ultraviolet light incident to the illumination optical system 140 and may allow light to be incident to the projection optical system 160. The projection optical system 160 may be configured as an imaging optical system disposed between the mask stage 150 and the substrate stage 170. For example, extreme ultraviolet light passing through the illumination optical system 140 may be structured according to a pattern shape including a reflective multilayer film and an absorption layer on the mask 155 and incident to the projection optical system 160.

The extreme ultraviolet light may be structured to include at least second-order diffraction light based on the pattern on the mask 155. The structured extreme ultraviolet light may be incident to the projection optical system 160 while retaining information on the pattern shape included in the mask 155, and may be irradiated to the substrate 106 seated on the substrate stage 170 through the projection optical system 160 to form an image corresponding to the pattern shape included in the mask 155. For example, the structured extreme ultraviolet light may be irradiated to the photoresist layer included in the substrate 106 and may form a specific pattern on the photoresist layer. However, in example embodiments, the structured extreme ultraviolet light passing through the projection optical system 160 may be incident to a process object other than the substrate 106. The extreme ultraviolet light passing through the projection optical system 160 after being reflected from the mask 155 may be incident to an upper surface of the photoresist layer included in the substrate 106 at a specific angle of incidence.

The projection optical system 160 may include a plurality of projection mirrors 161-166. Each of the plurality of projection mirrors 161-166 may include a mirror body, and a reflective layer attached to a surface of the mirror body. Accordingly, each of the plurality of projection mirrors 161-166 may reflect the structured extreme ultraviolet light from the mask 155.

In an example embodiment illustrated in FIG. 1, it is assumed that a photolithography process may be performed on the substrate 106 inserted into the second working space 102 using extreme ultraviolet light, but an example embodiment thereof is not limited thereto. For example, to perform a photolithography process in the second working space 102, a lighting unit 130 configured to emit deep ultraviolet (DUV) light instead of extreme ultraviolet light may be installed in the second working space 102. The configurations of the illumination optical system 140 and the projection optical system 160 may also be changed, and the deep ultraviolet light emitted by the lighting unit 130 may pass through the mask 155 and may be incident to the substrate 106.

The substrate 106 inserted into the second working space 102 in which the photolithography process is performed, and seated on the substrate stage 170 may be configured as the substrate 106 performed the measurement task preferentially in the first working space 101. For example, a photoresist layer may be formed on the substrate 106 by a process of applying and heating a photoresist material, and the substrate 106 may be disposed in the first working space 101 and a measurement task to verify a thickness and a surface profile of the photoresist layer may be preferentially performed.

In an example embodiment, a measurement apparatus 120 installed in the first working space 101 may verify a surface profile and/or a thickness of a photoresist layer included in the substrate 105 by irradiating the substrate 105 disposed on the stage 110 with pulsed light (e.g., a pulse of light). The pulsed light irradiated by the measurement apparatus 120 to the substrate 105 may have a duration of several picoseconds to several femtoseconds. In an example embodiment, the duration of the pulsed light may be determined differently depending on the thickness of the photoresist layer included in the substrate 105.

A portion of the pulsed light irradiated to the substrate 105 may be reflected from the exposed surface of the photoresist layer. Another portion of the pulsed light irradiated to the substrate 105 may travel into the photoresist layer and may be reflected from a region below the surface of the photoresist layer. The sensor of the measurement apparatus 120 may generate an output signal in response to reflected light.

A controller configured to perform a measurement task (e.g., a measurement process) may recognize a first output signal generated by a first beam of reflected light reflected from a surface of a photoresist layer, and a second output signal generated by a second beam of reflected light reflected below a surface of a photoresist layer in a distinguished manner. For example, the controller may distinguish the first output signal generated by the first beam as different from the second output signal generated by the second beam. For example, the time required for the first beam of reflected light to reach the sensor may be different from the time required for the second beam of reflected light to reach the sensor. Also, the intensity of the first beam of reflected light detected by the sensor may be different from the intensity of the second beam of reflected light. The controller may distinguish between the first output signal and the second output signal using at least one of the time required to reach the sensor and the intensity of the light, and may measure the photoresist layer using at least one of the first output signal and the second output signal.

In an example embodiment, the controller may measure the photoresist layer by distinguishing a first beam of reflected light reflected from the surface of the photoresist layer from a second beam of reflected light reflected from the interior of the photoresist layer, thereby improving accuracy of the measurement task without increasing the incident angle of the pulsed light. Accordingly, the measurement apparatus 120 may be efficiently implemented in the limited first working space 101, and the yield of the photolithography process performed in the second working space 102 may be improved.

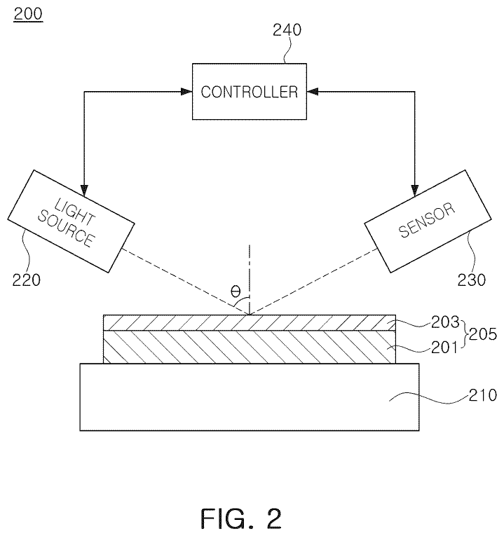

FIG. 2 is a diagram illustrating a semiconductor process apparatus according to an example embodiment.

Referring to FIG. 2, a semiconductor process apparatus 200 according to an example embodiment may include a stage 210, a light source 220, a sensor 230, and a controller 240. A substrate 205 may be seated on the stage 210, and the substrate 205 may include a base layer 201 and a photoresist layer 203 on the base layer 201. In an example embodiment, the base layer 201 may include a wafer including a semiconductor material such as silicon and a structure formed on the wafer. In an example embodiment, at least one other layer and/or at least one semiconductor element may be disposed between the base layer 201 and the photoresist layer 203.

The light source 220 may irradiate a surface of the photoresist layer 203 with light, and may irradiate, for example, pulsed light having a relatively short duration. The pulsed light irradiated by the light source 220 may be controlled by the controller 240. The pulsed light may have a specific incident angle θ, may be irradiated to the surface of the photoresist layer 203 and the reflected light may be incident to the sensor 230. The sensor 230 may generate an output signal in response to the reflected light, and the controller 240 may measure a thickness and a surface profile of the photoresist layer 203 using the output signal generated by the sensor 230.

In an example embodiment, the sensor 230 may be configured as a time of flight (ToF) sensor. The sensor 230 may include a plurality of photodiodes and a circuit configured to convert electric charges generated by the plurality of photodiodes in response to light into an output signal. The controller 240 may determine the intensity of the reflected light incident to each of the plurality of pixels, the time required for the reflected light to be incident to the sensor 230, and the like, using the output signal generated by the circuit included in the sensor 230.

The controller 240 may measure the photoresist layer 203 using the output signal generated by the sensor 230. For example, the controller 240 may distinguish, from the output signal generated by the sensor 230, a first output signal corresponding to reflected light reflected from the surface of the photoresist layer 203 from a second output signal corresponding to reflected light reflected from a position other than the surface of the photoresist layer 203. In an example embodiment, the controller 240 may determine the second output signal as noise in the output signal generated by sensor 230 and may filter the noise, may select only a first output signal and may measure the surface profile of the photoresist layer 203 using the first output signal.

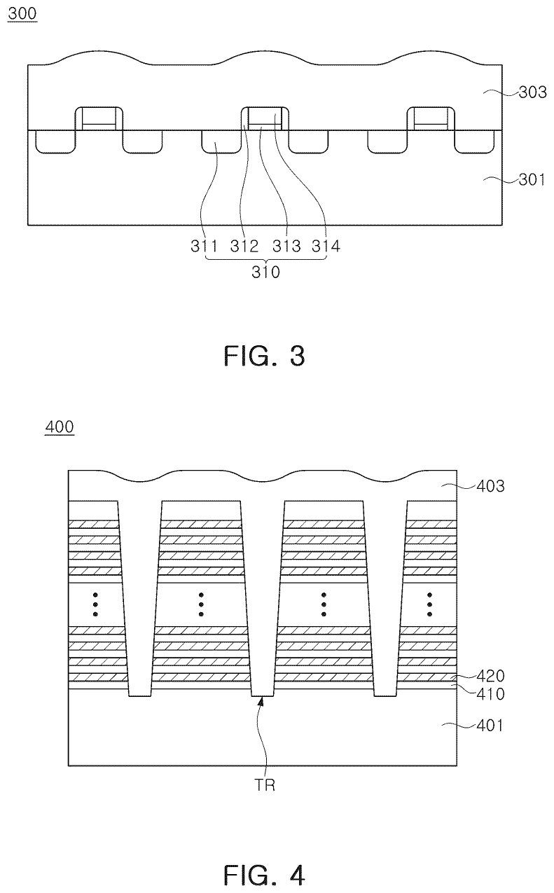

FIGS. 3 to 5 are diagrams illustrating operations of a semiconductor process apparatus according to an example embodiment.

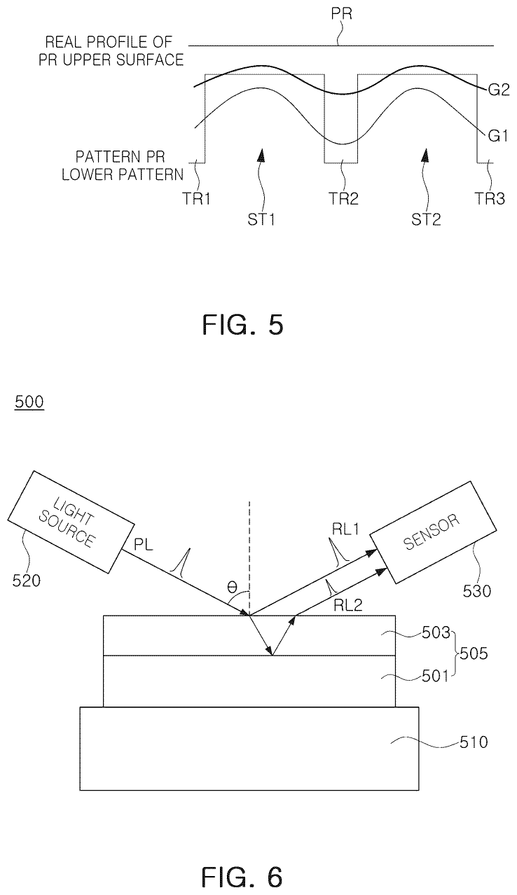

FIGS. 3 and 4 are diagrams illustrating example embodiments of substrates 300 and 400 inserted into a semiconductor process apparatus configured to perform a photolithography process. Referring to FIG. 3, the substrate 300 may include a semiconductor substrate 301, and a plurality of semiconductor devices 310 formed on the semiconductor substrate 301. For example, each of the plurality of semiconductor devices 310 may include an active region 311 and a gate structure 312-314, and the gate structure 312-314 may include a gate spacer 312, a gate insulating layer 313, and a gate electrode layer 314.

A photoresist layer 303 may be formed on the semiconductor substrate 301. In an example embodiment, the photoresist layer 303 may be formed by a spin coating process of spraying photoresist material to the semiconductor substrate 301 and rotating the semiconductor substrate 301, and a baking process of removing a solvent from the photoresist material applied on the semiconductor substrate 301 and hardening the photoresist material.

In the spin coating process, the semiconductor substrate 301 may rotate at an appropriate speed such that the photoresist material may be applied as uniformly as possible. However, as illustrated in FIG. 3, the surface of the photoresist layer 303 may not be formed to a uniform level due to the gate structures 312-314 formed to protrude from the upper surface of the semiconductor substrate 301.

Referring to FIG. 4, the substrate 400 may include a semiconductor substrate 401, a plurality of insulating layers 410 and a plurality of gate electrode layers 420 alternately stacked on the upper surface of the semiconductor substrate 401. A plurality of insulating layers 410 and a plurality of gate electrode layers 420 may be divided into a plurality of regions by trenches TR, and for example, the trenches TR may be formed to a depth penetrating a portion of the semiconductor substrate 401. The substrate 400 according to an example embodiment illustrated in FIG. 4 may be used in a process of manufacturing a vertical NAND flash memory.

A photoresist layer 403 may be formed on the semiconductor substrate 401, and the method of forming the photoresist layer 403 may be similar to the example described above with reference to FIG. 3. Due to trenches TR dividing a plurality of insulating layers 410 and a plurality of gate electrode layers 420 into a plurality of regions, a surface of the photoresist layer 403 may have a curvature as illustrated in FIG. 4, and accordingly, the surface of the photoresist layer 403 may not be formed on a uniform level.

As described with reference to FIGS. 3 and 4, when the levels of surfaces of the photoresist layers 303 and 403 are not uniform, a defect rate in the photolithography process may increase. Accordingly, prior to inputting the substrates 300 and 400 into the photolithography process, the surface profiles of the photoresist layers 303 and 403 may be measured by preferentially performing a measurement task, and if desired, the already formed photoresist layers 303 and 403 may be removed and the photoresist layers may be re-formed.

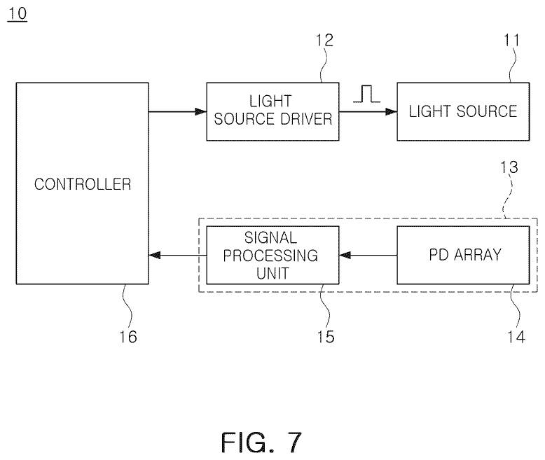

Accordingly, to improve the yield of the photolithography process, it may be necessary to improve accuracy of the process of measuring the levels (e.g., vertical levels, vertical positions, or heights) of surfaces of the photoresist layers 303 and 403 prior to the photolithography process. However, as described with reference to FIGS. 3 and 4, the photoresist layers 303 and 403 may be formed while structures of various shapes and sizes are formed on the semiconductor substrates 301 and 401, and the structures formed on the semiconductor substrates 301 and 401 may cause a decrease in accuracy of the measurement process. Hereinafter, an example embodiment will be described with reference to FIG. 5.

In an example embodiment illustrated in FIG. 5, it is assumed that the surface (e.g., the upper surface) of the photoresist layer PR is formed to have a uniform level. Structures ST1 and ST2 distinguished by trenches TR1-TR3 may be present below the photoresist layer PR, and a pattern due to the structures ST1 and ST2 may be exhibited.

The first profile G1 and the second profile G2 in FIG. 5 may be surface profiles of the photoresist layer PR determined by irradiating the surface of the photoresist layer PR with continuous light and measuring the photoresist layer PR by separating the reflected light reflected from the photoresist layer PR by a beam splitter. The first profile G1 may represent the result of irradiating the surface of the photoresist layer PR with light in the visible wavelength range, and the second profile G2 may represent the result of irradiating the surface of the photoresist layer PR with light in the ultraviolet wavelength band. As illustrated in FIG. 5, when measuring the photoresist layer PR by irradiating the surface of the photoresist layer PR with continuous light, the structures ST1 and ST2 below the photoresist layer PR may affect the profiles G1 and G2 obtained as measurement results.

In an example embodiment, instead of continuous light, pulsed light having a duration of several picoseconds to several femtoseconds may be irradiated to the surface of the photoresist layer PR to measure the surface profile of the photoresist layer PR. A portion of the pulsed light may be reflected from the surface of the photoresist layer PR, and the other portion may be reflected after traveling into and/or through the photoresist layer PR. The reflected light may be converted into an output signal by the ToF sensor. The ToF sensor may generate raw data including information such as the intensity of the reflected light, and the time point at which the reflected light reaches the ToF sensor, and may provide the raw data to the controller. The controller may control the ToF sensor and the light source, and may measure the surface profile of the photoresist layer PR by referring to the raw data. For example, the controller may identify an output signal corresponding to reflected light reflected from the surface of the photoresist layer PR based on the intensity of the reflected light in the raw data, and the time at which the reflected light reaches the ToF sensor, and may accurately determine the surface profile of the photoresist layer PR based on the output signal. The controller may effectively remove noise caused by the influence of structures ST1 and ST2 present below the photoresist layer PR in the raw data generated by the ToF sensor, and may measure the surface profile of the photoresist layer PR similarly to the actual profile.

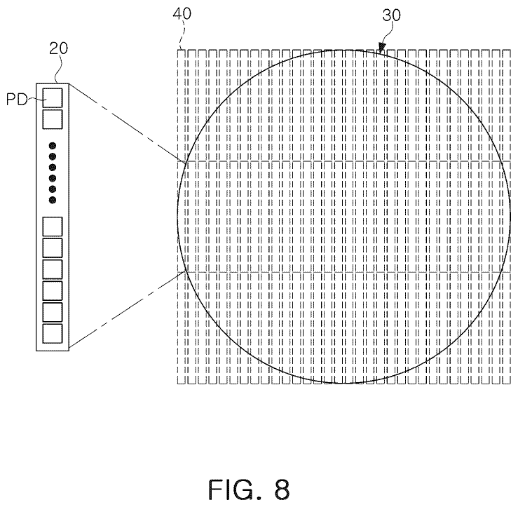

FIG. 6 is a diagram illustrating an operation of a semiconductor process apparatus according to an example embodiment.

Referring to FIG. 6, a semiconductor process apparatus 500 according to an example embodiment may include a stage 510, a light source 520, and a sensor 530. A substrate 505 including a base layer 501 and a photoresist layer 503 may be seated on the stage 510, and the base layer 501 may include a plurality of structures. The semiconductor process apparatus 500 may be configured as an apparatus for a photolithography process, and the stage 510 may be installed in a space separated from a space in which the photolithography process is performed. Prior to the photolithography process, a process of measuring a surface profile of the photoresist layer 503 included in the substrate 505 seated on the stage 510 may be performed in advance.

The light source 520 may irradiate a pulsed light PL of a specific wavelength band (e.g., a first wavelength band) toward the photoresist layer 503. The pulsed light PL may be irradiated toward the photoresist layer 503 for a relatively short duration, and for example, the duration may be several picoseconds to several femtoseconds. The pulsed light PL may form a specific incident angle θ with the surface of the photoresist layer 503, and the incident angle θ may be 75 degrees or less. The incident angle θ may be the angle between the direction of travel of the pulsed light PL and a line perpendicular to the surface of the photoresist layer 503. The light source 520 may irradiate one or more pulses of light PL of the specific wavelength band toward the photoresist layer 503. In a case when multiple pulses of light are irradiated by the light source 520, they may be separated from each other by a sufficient time period to enable the sensor 530 to sense a first beam of reflected light RL1 and a second beam of reflected light RL2 for each of the pulses of light.

A portion of the pulsed light PL irradiated to the photoresist layer 503 may be reflected from the surface of the photoresist layer 503 and may reach the sensor 530 as a first beam of reflected light RL1. Another portion (e.g., the remaining portion) of the pulsed light PL may travel into the photoresist layer 503 without being reflected from the surface of the photoresist layer 503. The pulsed light PL traveling into the photoresist layer 503 may be reflected, for example, at a boundary between structures of the photoresist layer 503 and the base layer 501 and may reach the sensor 530 as a second beam of reflected light RL2.

The sensor 530 may include photodiodes configured to generate electric charges in response to the first beam of reflected light RL1 and the second beam of reflected light RL2, and a circuit configured to convert the electric charges generated in the photodiodes into an output signal. In an example embodiment, the photodiodes may be arranged in a line shape in one direction, and in this case, the sensor 530 may scan the substrate 505 by a line-scanning method and may measure the surface profile of the photoresist layer 503.

The controller connected to the sensor 530 may obtain only the output signal generated by the first beam of reflected light RL1 other than the second beam of reflected light RL2 by filtering the output signal generated relatively late from the output signal output by the sensor 530. For example, the first beam of reflected light RL1 may arrive at the sensor 530 at a first time point that is earlier than a second time point at which the second beam of reflected light RL2 arrives at the sensor 530, and the controller may generate the output signal using only the first beam of reflected light RL1, without using the second beam of reflected light RL2. The controller may determine the surface profile of the photoresist layer 503 based on the output signal generated by the first beam of reflected light RL1.

In an example embodiment, the intensity of the first beam of reflected light RL1 may be different from the intensity of the second beam of reflected light RL2. For example, the intensity of the second beam of reflected light RL2 reflected after traveling into the photoresist layer 503 may be weaker than the intensity of the first beam of reflected light RL1 directly reflected from the surface of the photoresist layer 503. The controller may select the output signal generated by the first beam of reflected light RL1 by filtering the output signal having relatively weak intensity, and may determine the surface profile of the photoresist layer 503 based on the output signal generated by the first beam of reflected light RL1. In example embodiments, the controller may also filter the output signal generated by the second beam of reflected light RL2 by considering both the intensity difference of the output signal received from the sensor 530 and the difference in time point at which the output signal is generated.

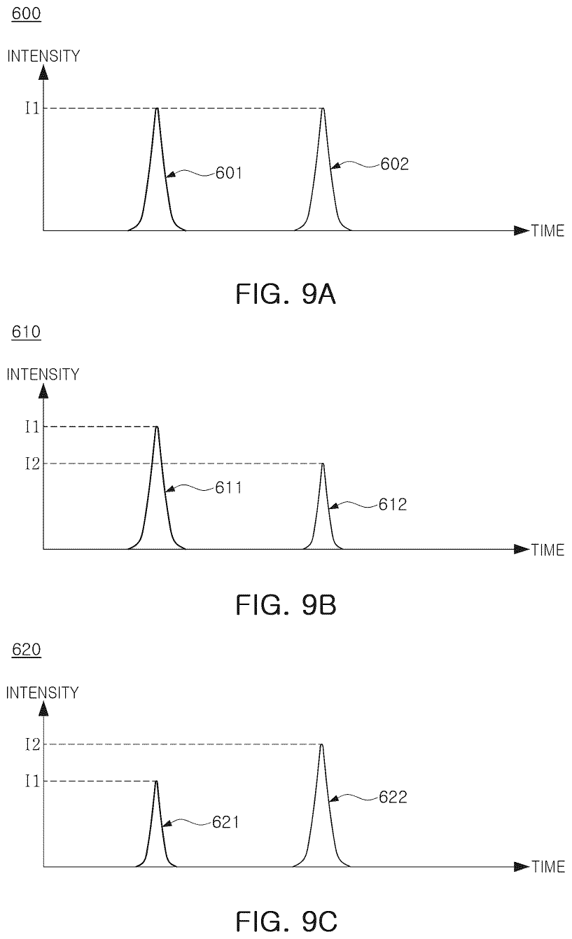

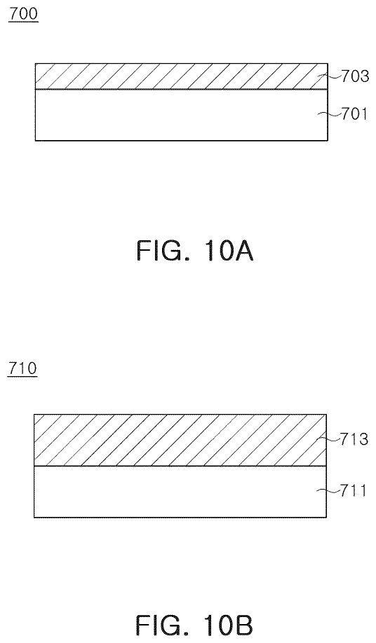

FIGS. 7 and 8 are diagrams illustrating operations of a semiconductor process apparatus according to an example embodiment.

Referring to FIG. 7, a semiconductor process apparatus 10 according to an example embodiment may include a light source 11, a light source driver 12, a sensor 13, and a controller 16. The sensor 13 may include a photodiode (PD) array 14 including a plurality of photodiodes and a signal processing unit 15, and the plurality of photodiodes included in the PD array 14 may be arranged one-dimensionally or two-dimensionally.

The light source driver 12 may control the light source 11 to output pulsed light in response to control from the controller 16. The light source driver 12 may output an optical control signal to the light source 11, and the intensity and the duration of the pulsed light may be determined by the optical control signal. The light source 11 may emit pulsed light in a specific wavelength band, for example, a visible light wavelength band, and the pulsed light emitted by the light source 11 may be irradiated to a photoresist layer.

A plurality of photodiodes included in the PD array 14 may generate electric charges in response to receiving reflected light. The electric charges generated from the plurality of photodiodes may be transferred to the signal processing unit 15 in the form of electrical signals, and the signal processing unit 15 may convert an electrical signal into a digital signal and may transfer the signal to the controller 16. In example embodiments, the signal processing unit 15 may perform a signal processing task such as amplifying an electrical signal or a digital signal. In an example embodiment, at least one of the light source driver 12 and the signal processing unit 15 may be implemented in the controller 16.

The controller 16 may control a duration and intensity of pulsed light emitted by the light source 11 and may perform a measurement process based on an electrical signal generated by the sensor 13. For example, the controller 16 may perform a measurement process of determining the surface profile of the photoresist layer irradiated with pulsed light, and a thickness of the photoresist layer. In example embodiments, the controller 16 may also determine whether an additional process, such as reapplying the photoresist layer, is necessary based on the results of the measurement process.

When the plurality of photodiodes included in the PD array 14 are arranged in one direction, the controller 16 may perform the measurement process by a line-scanning method. For example, the controller 16 may drive the light source 11 to irradiate different target regions with pulsed light multiple times with respect to a substrate including a photoresist layer, and may control the sensor 13 to detect reflected light for each of the target regions. The controller 16 may receive an electrical signal generated by detecting the reflected light for each of the target regions by the sensor 13, and may determine a surface profile of the photoresist layer and/or a thickness of the photoresist layer based on the electrical signal.

FIG. 8 may be a diagram describing a measurement process by a line-scanning method. In an example embodiment illustrated in FIG. 8, a substrate 30 including a photoresist layer may be a wafer. When the substrate 30 is inserted into a stage, a light source may irradiate a plurality of target regions 40 with pulsed light in sequence. When the light source is driven to irradiate one of the target regions 40 with pulsed light, a sensor may move to a position which may receive reflected light reflected from the target region 40. The plurality of target regions 40 may be defined to be arranged in directions parallel to the surface of the substrate 30. For example, each target region 40 may extend in a first direction parallel to the surface of the substrate 30, and the plurality of target regions 40 may be arranged in a second direction parallel to the surface of the substrate 30 that is perpendicular to the first direction.

The light source 11 may sequentially irradiate a plurality of target regions 40 with pulsed light, and the sensor may generate an electrical signal in response to reflected light reflected from each of the plurality of target regions 40. As illustrated in FIG. 8, the PD array 20 included in the sensor may include a plurality of photodiodes PD arranged in one direction, and the number of the plurality of photodiodes PD may be varied in example embodiments. For example, the number of the plurality of photodiodes PD may be several tens.

Each of the plurality of target regions 40 may be defined to extend in one direction in which the plurality of photodiodes 20 are arranged in the PD array 20 of the sensor. A length of each of the plurality of target regions 40 may be smaller than the maximum length of the substrate 30 in one direction. For example, when the substrate 30 is a wafer, a length of each of the plurality of target regions 40 may be smaller than a diameter of the wafer.

The number of target regions 40 to be irradiated with pulsed light to measure the photoresist layer in the entire substrate 30 and the area of each of the target regions 40 may be determined based on the size of the substrate 30, and the field of view (FOV) which the PD array 20 may cover at one time. In an example embodiment, the number of target regions 40 required to measure the photoresist layer in the entire substrate 30 may be tens of thousands or more.

The controller may receive an electrical signal generated by the PD array 20 in response to the reflected light emitted from each of the plurality of target regions 40 and may measure a surface profile and a thickness of the photoresist layer by processing the electrical signal. Since the pulsed light irradiated to each of the plurality of target regions 40 has a relatively short duration, the reflected light incident to each of the plurality of photodiodes PD included in the PD array 20 may also have a relatively short duration similarly to the pulsed light.

As described above with reference to FIG. 6, the reflected light incident to the PD array 20 may include a first beam of reflected light generated when the pulsed light is directly reflected from the surface of the photoresist layer, and a second beam of reflected light generated by the pulsed light reflected after entering the photoresist layer. Since the first beam of reflected light and the second beam of reflected light may have a relatively short duration similarly to the pulsed light, the controller may distinguish between the first electrical signal generated by the PD array 20 in response to the first beam of reflected light and the second electrical signal generated in response to the second beam of reflected light. For example, the controller may distinguish between the first electrical signal and the second electrical signal based on the intensity and/or the time point at which the signal is generated. Accordingly, the controller may filter the second electrical signal corresponding to the second beam of reflected light from the output signal of the PD array 20, thereby improving accuracy of the task of measuring the surface profile of the photoresist layer.

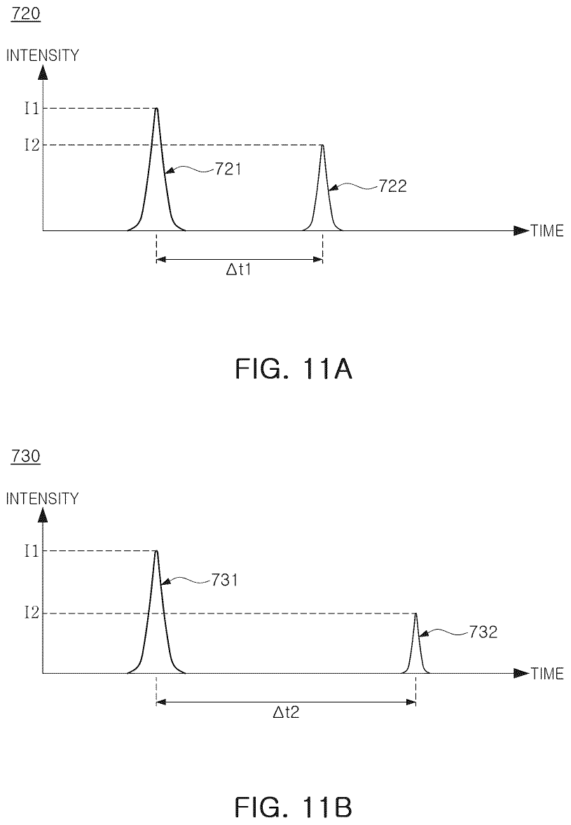

FIGS. 9A to 9C are diagrams illustrating operations of a semiconductor process apparatus according to an example embodiment.

FIGS. 9A to 9C are diagrams illustrating an output signal output by a sensor configured to receive reflected light generated by pulsed light irradiated to a substrate in a semiconductor process apparatus according to an example embodiment. First, referring to FIG. 9A, the sensor configured to receive reflected light may provide an output signal 600 to a controller, and the output signal 600 may include a first output signal 601 and a second output signal 602. In an example embodiment illustrated in FIG. 9A, the first output signal 601 and the second output signal 602 may have the same first intensity I1.

The first output signal 601 output preferentially at a relatively early time point may be a signal generated by the sensor by the first beam of reflected light directly reflected from the surface of the photoresist layer. The second output signal 602 output at a relatively late time point may be a signal generated by the second beam of reflected light reflected after the photoresist layer by the sensor. Since each of the first beam of reflected light and the second beam of reflected light may be generated by reflecting pulsed light having a relatively short duration, the first output signal 601 and the second output signal 602 may also be generated in a pulse form as illustrated in FIG. 9A.

The controller may receive the first output signal 601 and the second output signal 602 from the sensor, and may distinguish between the first output signal 601 and the second output signal 602 based on the time point at which the first output signal 601 and the second output signal 602 are generated, or the time point at which the first output signal 601 and the second output signal 602 are received from the sensor. The second output signal 602 generated by the sensor in response to the second beam of reflected light reflected after traveling into the photoresist layer may be noise in determining the surface profile of the photoresist layer.

Accordingly, the controller may filter the second output signal 602 as noise and may measure the surface profile of the photoresist layer using the first output signal 601. As described above with reference to FIG. 8, while the pulsed light is irradiated to each of the plurality of target regions defined on the substrate, the sensor may generate output signals 601 and 602 as illustrated in FIG. 9A for each of the plurality of target regions. The controller may measure the surface profile of the photoresist layer with reference to the output signals 601 and 602 generated for each of the target regions. In example embodiments, the controller may also measure a thickness of the photoresist layer in at least one of the target regions with reference to a second output signal 602 affected by the profile of a structure present below the photoresist layer.

Referring to FIG. 9B, a sensor configured to receive reflected light may provide an output signal 610 to a controller, and the output signal 610 may include a first output signal 611 and a second output signal 612. In an example embodiment illustrated in FIG. 9B, a second intensity I2 of the second output signal 612 may be relatively less than a first intensity I1 of the first output signal 611. This may be because an intensity of a first beam of reflected light directly reflected from a surface of a photoresist layer may be greater than an intensity of a second beam of reflected light traveling into the photoresist layer.

In an example embodiment illustrated in FIG. 9B, the controller may identify the second output signal 612 using the time points at which each of the first output signal 611 and the second output signal 612 is generated or output by the sensor, and/or a difference between the first intensity I1 and the second intensity I2. The controller may filter the second output signal 612 and may measure the surface profile of the photoresist layer by referring to the first output signal 611.

Referring to FIG. 9C, the output signal 620 provided to the controller by the sensor receiving the reflected light may include the first output signal 621 and the second output signal 622. In an example embodiment illustrated in FIG. 9C, the first intensity I1 of the first output signal 621 may be less than the second intensity I2 of the second output signal 622. This may be because, in some embodiments, the intensity of the first beam of reflected light directly reflected from the surface of the photoresist layer may be weaker than the intensity of the second beam of reflected light traveling into the photoresist layer.

The controller may identify the second output signal 622 using the time point at which the first output signal 621 and the second output signal 622 are generated from or output by the sensor, and/or a difference between the first intensity I1 and the second intensity I2. The controller may filter the second output signal 622 and may measure the surface profile of the photoresist layer with reference to the first output signal 621. In an example embodiment illustrated in FIG. 9C, the controller may increase accuracy of the measurement task by increasing the intensity of the first beam of reflected light reflected from the surface of the photoresist layer, and to this end, the controller may increase an incident angle of the pulsed light irradiated to the surface of the photoresist layer.

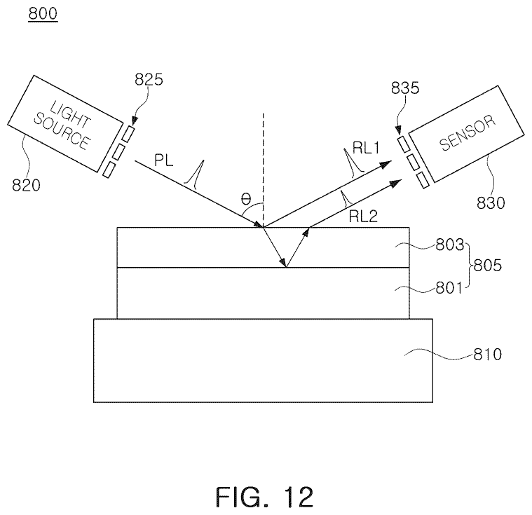

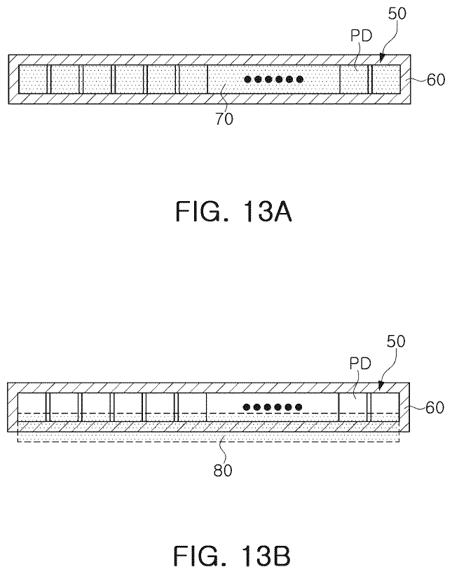

FIGS. 10A, 10B, 11A, and 11B are diagrams illustrating operations of a semiconductor process apparatus according to an example embodiment.

FIGS. 10A and 10B are diagrams illustrating substrates 700 and 710 inserted into a semiconductor process apparatus according to an example embodiment while photoresist layers 703 and 713 are applied thereon. Referring to FIGS. 10A and 10B, the substrates 700 and 710 which may be inserted into a semiconductor process apparatus according to an example embodiment may include base layers 701 and 711 and the photoresist layers 703 and 713. The semiconductor process apparatus may perform a photolithography process by irradiating the photoresist layers 703 and 713 with extreme ultraviolet light.

The photoresist layers 703 and 713 may be applied in another apparatus connected to the semiconductor process apparatus. For example, photoresist for forming photoresist layers 703 and 713 may be applied on the base layers 701 and 711 by a spin coating process, and the photoresist may be hardened by removing solvent by a baking process, thereby forming the photoresist layers 703 and 713.

A thickness of the photoresist layers 703 and 713 may be varied depending on subsequent processes including a photolithography process as illustrated in FIGS. 10A and 10B. A thickness of the second photoresist layer 713 included in the second substrate 710 according to an example embodiment illustrated in FIG. 10B may be relatively greater than the thickness of the first photoresist layer 703 included in the first substrate 700 according to an example embodiment illustrated in FIG. 10A.

In an example embodiment, in the process of measuring the surface profile of the photoresist layers 703 and 713 prior to the photolithography process, a duration of the pulsed light irradiated to the surface of the photoresist layers 703 and 713 may be determined differently depending on the thicknesses of the photoresist layers 703 and 713. In an example embodiment, the duration of the pulsed light irradiated to the first photoresist layer 703 having a relatively small thickness may be shorter than the duration of the pulsed light irradiated to the second photoresist layer 713 having a relatively large thickness. This may be to clearly distinguish between the first beam of reflected light reflected on the surface of the photoresist layers 703 and 713 and the second beam of reflected light reflected after traveling into the photoresist layers 703 and 713.

FIG. 11A is a graph illustrating an output signal 720 generated by a sensor while irradiating a first substrate 700 with pulsed light, and FIG. 11B is a graph illustrating an output signal 730 generated by a sensor while irradiating a second substrate 710 with pulsed light. Referring to FIG. 11A, a first output signal 721 generated by a first beam of reflected light reflected from the surface of the first photoresist layer 703 and a second output signal 722 generated by a second beam of reflected light may be generated with a first time difference Δt1 therebetween.

Referring to FIG. 11B, a second time difference Δt2 longer than the first time difference Δt1 may appear between the first output signal 731 generated by the first beam of reflected light reflected from the surface of the second photoresist layer 713 and the second output signal 732 generated by the second beam of reflected light. This may be because the thickness of the second photoresist layer 713 may be relatively greater than the thickness of the first photoresist layer 703. Due to a difference in thicknesses between the first photoresist layer 703 and the second photoresist layer 713, the difference between the first intensity I1 of the first output signal 721 and 731 and the second intensity I2 of the second output signal 722 and 732 may also appear greater in the second substrate 710.

When irradiating the first photoresist layer 703 having a relatively smaller thickness with pulsed light having a duration the same as a duration of the pulsed light irradiated to the second photoresist layer 713, portions of the first output signal 721 and the second output signal 722 may overlap each other and may not be clearly distinct from each other. In an example embodiment, since the first photoresist layer 703 included in the first substrate 700 has a thickness smaller than a thickness of the second photoresist layer 713 included in the second substrate 710, the first substrate 700 may be irradiated with pulsed light of shorter duration. Accordingly, the first output signal 721 and the second output signal 722 may be clearly distinct from each other, and the surface profile of the first photoresist layer 703 may be accurately measured.

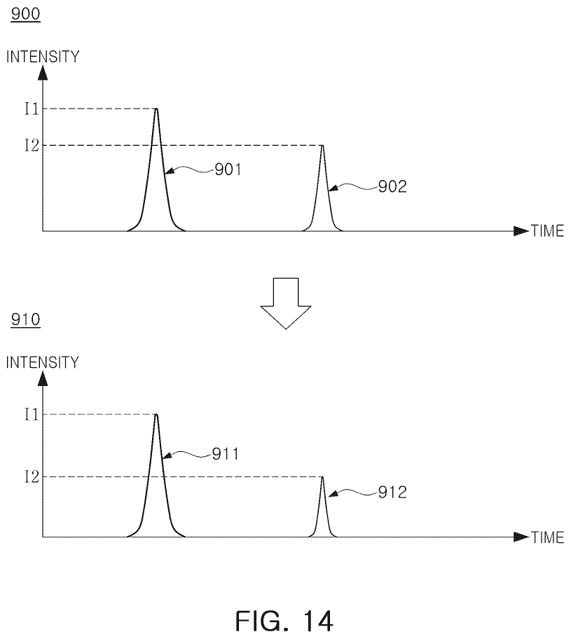

FIGS. 12 to 15 are diagrams illustrating operations of a semiconductor process apparatus according to an example embodiment.

Referring to FIG. 12, a semiconductor process apparatus 800 according to an example embodiment may include a stage 810, a light source 820, and a sensor 830. A substrate 805 including a base layer 801 and a photoresist layer 803 may be seated on the stage 810, and the base layer 801 may include a plurality of structures. The semiconductor process apparatus 800 may be an apparatus for a photolithography process, and the stage 810 may be installed in a space separated from a space in which the photolithography process is performed. Prior to the photolithography process, a process of measuring a surface profile of the photoresist layer 803 included in the substrate 805 seated on the stage 810 may be performed in advance.

The light source 820 may irradiate a pulsed light PL of a specific wavelength band toward the photoresist layer 803. The pulsed light PL may be irradiated toward the photoresist layer 803 for a relatively short duration, and for example, the duration may be several picoseconds to several femtoseconds. The pulsed light PL may form a specific incident angle θ with the surface of the photoresist layer 803 (e.g., an angle between the traveling direction of the pulsed light PL and a direction perpendicular to the surface of the stage 810), and a portion of the pulsed light PL may be reflected from the surface of the photoresist layer 803 and may reach the sensor 830 as a first beam of reflected light RL1.

The other portion of the pulsed light PL may travel into the photoresist layer 803 without being reflected from the surface of the photoresist layer 803. The pulsed light PL traveling into the photoresist layer 803 may be reflected, for example, from a boundary between structures of the photoresist layer 803 and the base layer 801 and may reach the sensor 830 as a second beam of reflected light RL2. The sensor 830 may include photodiodes configured to generate electric charges in response to the first beam of reflected light RL1 and the second beam of reflected light RL2, and may generate an output signal using electric charges generated in the photodiodes.

A controller configured to receive an output signal from the sensor 830 may distinguish between a first output signal corresponding to the first beam of reflected light RL1 and a second output signal corresponding to the second beam of reflected light RL2, and may determine a surface profile of the photoresist layer 803. For example, the controller may distinguish between the first output signal and the second output signal based on a time point at which each of the first output signal and the second output signal is generated or output, and/or an intensity difference between the first output signal and the second output signal.

In an example embodiment, the controller may filter the second output signal as noise from the entire output signal and may measure the surface profile of the photoresist layer 803. When the first output signal and the second output signal are clearly distinct from each other, measurement accuracy for the surface profile of the photoresist layer 803 may also be improved.

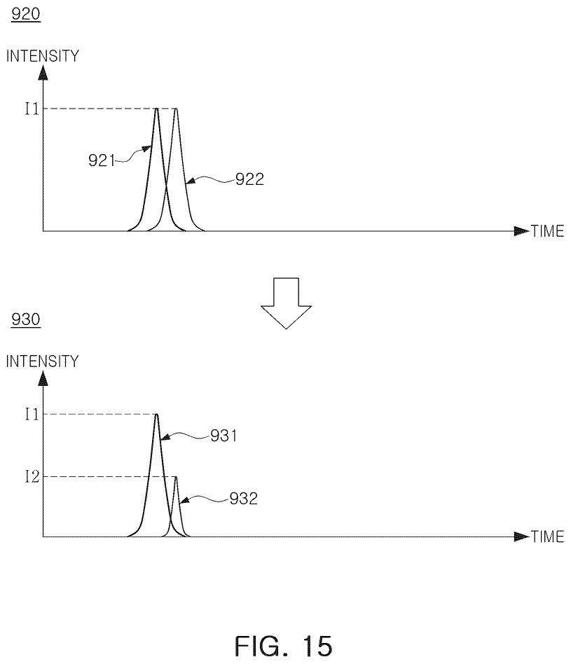

In an example embodiment illustrated in FIG. 12, grid structures 825 and 835 may be disposed in a path in which the pulsed light PL emitted from the light source 820 travels to the substrate 805, and a path in which the first beam of reflected light RL1 and the second beam of reflected light RL2 reflected from the substrate 805 travel to the sensor 830, respectively. For example, the grid structure 825 may be disposed in the path between the light source 820 and the substrate 805, and the grid structure 835 may be disposed in the path between the substrate 805 and the sensor 830. For example, the intensity change of the first beam of reflected light RL1 due to the grid structure 835 may be smaller than the intensity change of the second beam of reflected light RL2 due to the grid structure 835. In other words, a ratio of the second beam of reflected light RL2 blocked and not transmitted to the sensor 830 by the grid structure 835 may be higher than a ratio of the first beam of reflected light RL1 blocked by the grid structure 835. Hereinafter, the example embodiment will be described in greater detail with reference to FIGS. 13A and 13B.

Referring to FIG. 13A and FIG. 13B, a grid structure 60 may be disposed at a front end of a sensor 50 in which a plurality of photodiodes PD are disposed in one direction. FIG. 13A is a diagram describing a traveling path of a first beam of reflected light 70, and FIG. 13B may be a diagram describing a traveling path of a second beam of reflected light 80. The grid structure 60 may have at least one slit transmitting light.

Referring to FIG. 13A, almost the entirety of the first beam of reflected light 70 may pass through the slit of the grid structure 60 and may be incident to the sensor 50. On the other hand, referring to FIG. 13B, more than half of the second beam of reflected light 80 may be blocked by the grid structure 60 and may not be incident to the sensor 50.

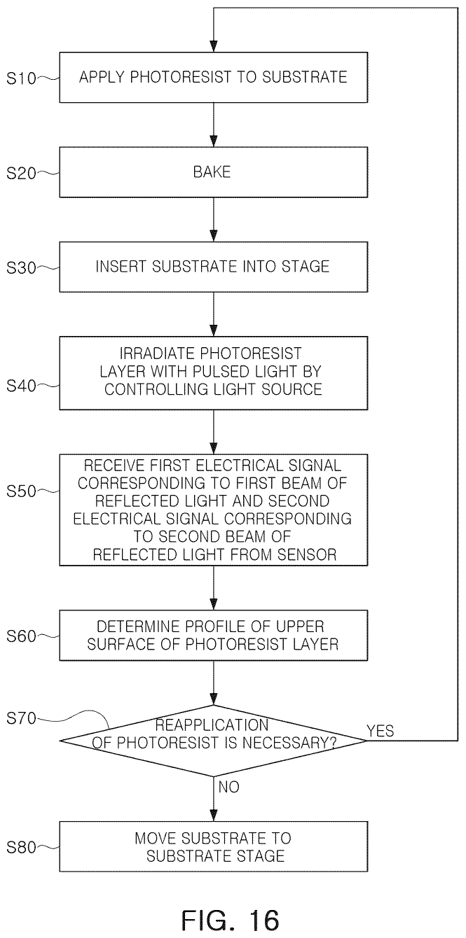

Referring to FIG. 14, the output signal 900 illustrated in the first graph may be a first output signal 901 and a second output signal 902 on the assumption that no grid structure 60 is provided, and the output signal 910 of the second graph may be a first output signal 911 and a second output signal 912 on the assumption that the grid structure 60 is disposed at a front end of the sensor 50. As illustrated in FIG. 14, a difference between the first intensity I1 of the first output signal 901 and the second intensity I2 of the second output signal 902 may be greater when the grid structure 60 is present than when no grid structure 60 is provided. As described above, by disposing the grid structure 60, the controller may more clearly distinguish the first output signal 911 from the second output signal 912 from the output signal 910 of the sensor 50, and may measure the surface profile of the photoresist layer more accurately.

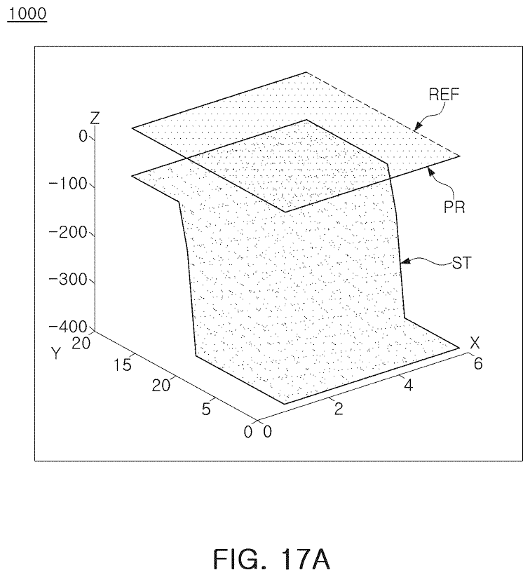

Referring to FIG. 15, the output signal 920 illustrated in the first graph may be the first output signal 921 and the second output signal 922 on the assumption that no grid structure 60 is provided, and the output signal 930 in the second graph may be the first output signal 931 and the second output signal 932 on the assumption that the grid structure 60 is disposed at a front end of the sensor 50. In an example embodiment illustrated in FIG. 15, the first output signals 921 and 931 and the second output signals 922 and 932 may overlap each other. As illustrated in the first graph in FIG. 15, when the first output signal 921 and the second output signal 922 overlap each other and the degrees of intensity I1 thereof are not significantly different, it may be difficult to selectively separate the first output signal 921 caused by the reflected light reflected from the surface of the photoresist layer.

In an example embodiment, the issues as above may be addressed by disposing the grid structure 60 at the front end of the sensor 50. Referring to the second graph in FIG. 15, by disposing the grid structure 60, the intensity of the second beam of reflected light 932 may be relatively further reduced. Since the grid structure shields a portion of the second beam of reflected light 932, the first beam of reflected light 931 may have the first intensity I1 and the second beam of reflected light 932 may have the second intensity I2, and the controller may clearly distinguish between the first output signal 931 and the second output signal 932 based on the intensity difference. Accordingly, the controller may accurately measure the surface profile of the photoresist layer.

As described above, in various example embodiments, the surface profile of the photoresist layer included in the substrate may be accurately measured using pulsed light having a specific duration. However, in example embodiments, an object of which a surface profile may be measured by irradiating the pulsed light may not be necessarily limited to the photoresist layer.

According to example embodiments, the controller may distinguish, from the output signal generated by the sensor, a first output signal generated by the sensor by a first beam of reflected light reflected from the surface of the substrate, and a second output signal generated by the sensor by a second beam of reflected light reflected after traveling to a region below the surface of the substrate. The controller may measure the surface profile based on the first output signal, and the surface profile measured herein may be a surface profile of the uppermost layer disposed at an uppermost end of the substrate and exposed.

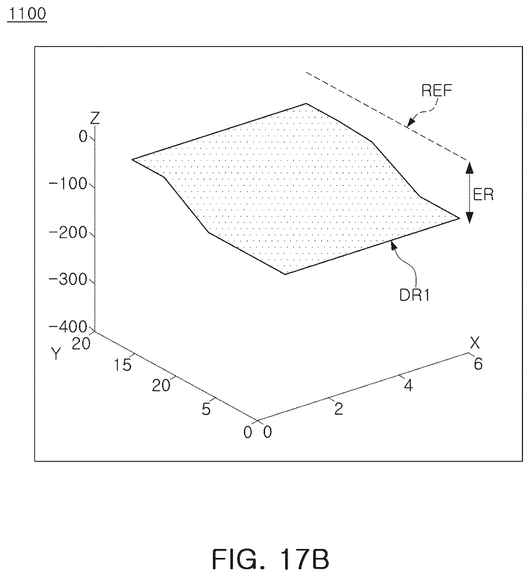

FIG. 16 is a flowchart illustrating an operation of a semiconductor process apparatus according to an example embodiment.

Referring to FIG. 16, operation of a semiconductor process apparatus according to an example embodiment may start with applying photoresist to a substrate (S10). The photoresist may be applied by a spin coating process, may be evaporated from the solvent and may be hardened into the photoresist through a baking process (S20), thereby forming a photoresist layer.

When the photoresist layer is formed, a substrate may be inserted into a stage (S30). The stage may be disposed in a space in which a measurement task of identifying whether the photoresist layer is properly formed may be performed prior to a photolithography process of printing a desired pattern by irradiating the photoresist layer with light of a specific wavelength band, for example, extreme ultraviolet light. In the space in which the stage is disposed, a light source for irradiating the stage with light, and a sensor for detecting reflected light generated by the substrate mounted on the stage reflecting light may be installed.

When a substrate is inserted into the stage, a controller of the semiconductor process apparatus may irradiate a photoresist layer of the substrate with pulsed light by controlling a light source (S40). The pulsed light may have a specific wavelength band and a relatively short duration of several femtoseconds to several picoseconds. The pulsed light may be reflected by the substrate and may travel as reflected light to a sensor.

The sensor may include photodiodes configured to generate electric charges in response to the reflected light, and may generate a first electrical signal and a second electrical signal using the electric charges generated in the photodiodes. In an example embodiment, the first electrical signal may correspond to a first beam of reflected light, and the second electrical signal may correspond to a second beam of reflected light. The first beam of reflected light may be formed by pulsed light directly reflected from the surface of the photoresist layer and incident to the sensor, and the second beam of reflected light may be formed by pulsed light reflected after traveling to a region below the surface of the photoresist layer, that is, into the photoresist layer. The controller may receive a first electrical signal and a second electrical signal from the sensor (S50).

The controller may determine a profile of an upper surface of the photoresist layer using the signal received from the sensor (S60). The upper surface, which is an object of determination of a profile, may be a surface of the photoresist layer directly irradiated with the pulsed light and may be exposed. In an example embodiment, the controller may accurately determine the profile of the upper surface of the photoresist layer by separating a signal corresponding to the first beam of reflected light from a signal corresponding to the second beam of reflected light from a signal received from the sensor. As described above, the controller may separate the signal corresponding to the first beam of reflected light from the signal corresponding to the second beam of reflected light by referring to a difference in intensity of the signal and generation and/or reception time point of the signal.

The controller may determine whether reapplication of the photoresist is necessary based on the profile determined in operation S60 (S70). For example, when it is determined that the upper surface of the photoresist layer has excessive curvatures or that flatness does not meet a predetermined criterion according to a result of the determination in operation S60, the controller may perform the process (S10-S20) of forming the photoresist layer on the substrate again. In example embodiments, before applying the photoresist on the substrate to form the photoresist layer again, the already formed photoresist layer may be removed.

When it is determined that the profile of the upper surface of the photoresist layer satisfies a predetermined criterion as a result of operation S60, the controller may move the substrate to the substrate stage (S80). The substrate stage may be a stage installed in a space in which a photolithography process of printing a desired pattern is performed by irradiating the photoresist layer with extreme ultraviolet light.

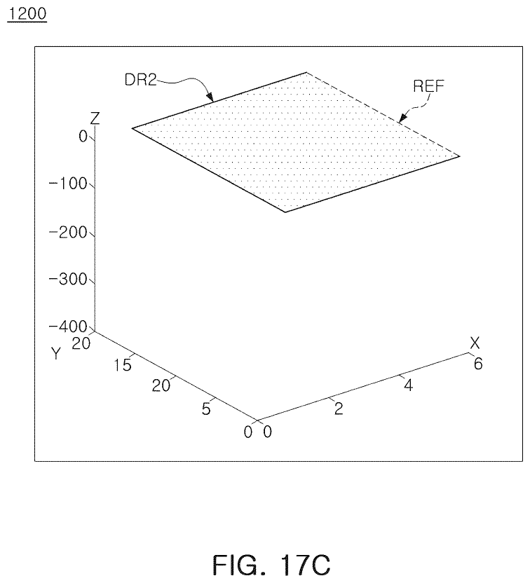

FIGS. 17A to 17C are diagrams illustrating operations of a semiconductor process apparatus according to an example embodiment.

Graph 1000 in FIG. 17A may be a diagram illustrating an actual structure of a substrate inserted into a semiconductor process apparatus according to an example embodiment. Referring to FIG. 17A, a surface of the photoresist layer PR may have a predetermined criterion level REF and may have a flat shape. A structure ST may be disposed below the photoresist layer PR in the Z-axis direction. The structure ST may have a specific shape in the X-axis, Y-axis, and Z-axis directions, and may have a relatively great level difference in the Z-axis direction particularly. For example, a vertical level (in the Z-axis direction) of a first portion of the structure ST at a first position in the Y-axis direction may be different from a vertical level of a second portion of the structure ST at a second position in the Y-axis direction.

When the photoresist layer PR is formed on the structure ST, a measurement task of verifying the surface profile of the photoresist layer PR may be performed before performing the photolithography process. Graph 1100 in FIG. 17B may be an example diagram illustrating the result of performing the measurement task by irradiating the photoresist layer PR with light using a light source configured to continuously output light. Referring to FIG. 17B, when performing a measurement task while irradiating the photoresist layer PR with continuous light, in the measurement result DR1, a level may be measured lower than the criterion level REF by the error ER, which is the actual level of the surface of the photoresist layer PR.

This may be because the structure ST present below the photoresist layer PR may affect properties of light irradiated to and reflected from the photoresist layer PR. When irradiating the photoresist layer PR with continuous light, light reflected directly from the surface of the photoresist layer PR and light traveling into the photoresist layer PR and reflected from an interfacial surface of the structure ST and the photoresist layer PR may be incident to the sensor in a mixed state. Also, since light is incident to the sensor continuously, it may be difficult to separate the signal corresponding to the light reflected directly from the surface of the photoresist layer PR from the signal output by the sensor.

In an example embodiment, by irradiating the photoresist layer PR with pulsed light, the above issues may be addressed and accuracy of the measurement task may be improved. Referring to the graph 1200 in FIG. 17C, by the measurement method of irradiating the photoresist layer PR with pulsed light as in the embodiment, the measurement result DR2 similar to the criterion level REF may be obtained.

By irradiating the photoresist layer PR with pulsed light, the first beam of reflected light directly reflected from the surface of the photoresist layer PR and the second beam of reflected light traveling into the photoresist layer PR and reflected from the structure ST and the interfacial surface of the photoresist layer PR may be clearly distinguished from each other. In an example embodiment, the time points at which the first output signal corresponding to the first beam of reflected light and the second output signal corresponding to the second beam of reflected light are generated by the sensor, the time points at which the controller receives the signals from the sensor, and the degrees of intensity of the signals may be different, and the controller may clearly distinguish the first output signal from the second output signal from the output signal of the sensor.

In an example embodiment, the controller may determine the surface profile of the photoresist layer PR only with the first output signal, and may obtain the measurement result DR having almost no error with the actual level REF of the photoresist layer PR as illustrated in FIG. 17C. Also, the thickness of the photoresist layer PR may also be determined with reference to the first output signal and the second output signal.

According to the aforementioned example embodiments, the measurement process of measuring the surface profile and the thickness of the photoresist layer may be performed on a substrate which may be put into the semiconductor process apparatus while a photoresist layer is applied thereon. By irradiating the photoresist layer with pulsed light and detecting the intensity of each of the reflected lights reflected from the surface and the internal region of the photoresist layer, the surface profile and thickness of the photoresist layer may be measured. Accuracy of the measurement process may be improved without excessively increasing an incident angle of pulsed light irradiated to the photoresist layer, such that the components required for the measurement process may be easily installed in the limited internal space of the semiconductor process apparatus, and yield of the photolithography process may be improved.

While the example embodiments have been illustrated and described above, it will be configured as apparent to those skilled in the art that modifications and variations could be made without departing from the scope of the present disclosure.

What is claimed is:

1. A semiconductor process apparatus, comprising:
a stage on which a substrate including a photoresist layer is configured to be seated;
a light source configured to irradiate a pulse of light toward the substrate;
a sensor configured to generate an output signal in response to reflected light reflected from the substrate; and
a controller configured to control the light source and the sensor and to measure the photoresist layer using the output signal,
wherein the controller is configured to obtain, from the output signal, a first output signal corresponding to a first beam of the reflected light reflected from a surface of the photoresist layer and a second output signal corresponding to a second beam of the reflected light reflected from a region below a surface of the photoresist layer, and to measure the photoresist layer using the first output signal and the second output signal.

2. The semiconductor process apparatus of claim 1, wherein the controller is configured to determine a surface profile of the photoresist layer using a difference between an intensity of the first output signal and an intensity of the second output signal.

3. The semiconductor process apparatus of claim 1, wherein the controller is configured to determine a surface profile of the photoresist layer using a time difference between a time point at which the first output signal is generated and a time point at which the second output signal is generated.

4. The semiconductor process apparatus of claim 1, wherein the controller is configured to set a duration of the pulse of light based on a thickness of the photoresist layer.

5. The semiconductor process apparatus of claim 1, wherein the sensor is a time-of-flight (ToF) sensor.

6. The semiconductor process apparatus of claim 5, wherein the sensor includes a plurality of photodiodes arranged in one direction.

7. The semiconductor process apparatus of claim 6, wherein the controller is configured to drive the light source such that the pulse of light is irradiated to each of a plurality of target regions, and to measure the photoresist layer using the first output signal and the second output signal generated by the sensor for each of the plurality of target regions, and
wherein the plurality of target regions are disposed along directions parallel to a surface of the substrate.

8. The semiconductor process apparatus of claim 7, wherein each of the plurality of target regions is defined to extend in one direction, and a length of each of the plurality of target regions is less than a maximum length of the substrate in the one direction.

9. The semiconductor process apparatus of claim 1, wherein the light source is configured to irradiate the pulse of light in a visible wavelength range.

10. The semiconductor process apparatus of claim 1, further comprising:
a grid structure disposed in a path on which the reflected light is configured to travel to the sensor,
wherein a change in intensity of the first beam of reflected light due to the grid structure is smaller than a change in an intensity of the second beam of reflected light due to the grid structure.

11. The semiconductor process apparatus of claim 1, wherein an incident angle of the pulse of light to a surface of the photoresist layer is 75 degrees or less.

12. The semiconductor process apparatus of claim 1, further comprising:
a first working space in which the stage and the light source are disposed;
a second working space separated from the first working space;
a second light source installed in the second working space and configured to output light of a specific wavelength band;
a mask stage on which a mask configured to reflect or transmit light is seated;
a substrate stage to which light reflected from or transmitted through the mask is irradiated;
an illumination optical system configured to transmit light between the second light source and the mask stage; and
a projection optical system configured to transmit light between the mask stage and the substrate stage.

13. The semiconductor process apparatus of claim 12, wherein the controller is configured to move the substrate to the substrate stage when the measurement of the photoresist layer is completed and a surface profile of the photoresist layer passes a predetermined criterion.

14. The semiconductor process apparatus of claim 12, wherein the controller is configured to perform a process of forming the photoresist layer again when the measurement of the photoresist layer is completed and a surface profile of the photoresist layer does not pass a predetermined criterion.

15. A semiconductor process apparatus, comprising:
a stage on which a substrate including a photoresist layer is configured to be seated;
a light source configured to irradiate a pulse of light having a predetermined duration in each of a plurality of target regions defined along a direction parallel to a surface of the substrate;
a sensor configured to receive reflected light reflected from each of the plurality of target regions; and
a controller configured to obtain, from an output signal generated by the sensor in response to the reflected light, a first output signal corresponding to a first beam of the reflected light reflected from a surface of the photoresist layer in each of the plurality of target regions,
wherein the controller is configured to measure a surface profile of the photoresist layer based on the first output signal.

16. The semiconductor process apparatus of claim 15,
wherein the sensor includes a photodiode (PD) array including a plurality of photodiodes arranged therein, and
wherein the controller is configured to set an area of each of the plurality of target regions based on a field of view (FOV) of the PD array.

17. The semiconductor process apparatus of claim 16, further comprising:
a grid structure disposed in a path on which the reflected light travels, the grid structure having a slit through which the reflected light passes,
wherein an intensity at which the first beam of the reflected light passes through the slit is stronger than an intensity at which a second beam of the reflected light not reflected from the surface of the photoresist layer passes through the slit.

18. The semiconductor process apparatus of claim 15, wherein the controller is configured to obtain the first output signal from the output signal based on at least one of a time point at which the first output signal is generated and an intensity of the first output signal.

19. The semiconductor process apparatus of claim 15, wherein the predetermined duration is in a range from several femtoseconds to several picoseconds.

20. A semiconductor process apparatus, comprising:
a stage on which a substrate is configured to be seated;
a light source configured to irradiate a pulse of light to a surface of the substrate;
a sensor configured to generate an output signal in response to reflected light reflected from the substrate; and
a controller configured to distinguish between a first output signal and a second output signal, the first output signal corresponding to a first beam of the reflected light directly reflected from the surface of the substrate, and the second output signal corresponding to a second beam of the reflected light traveling to a region below the surface of the substrate and reflected,
wherein the controller is further configured to measure a surface profile of the substrate using the first output signal.
